(19) United States
(12) Patent Application Publication
(10) Pub. No.: US 2025/0247154 A1
(43) Pub. Date: Jul. 31, 2025

(54) METHOD AND APPARATUS FOR GENERATING OPTICAL MODULATION AMPLITUDE SIGNAL ACCORDING TO AVERAGE OUTPUT POWER CONTROL SETTING OF LASER DIODE AND ASSOCIATED METHOD

(71) Applicant: Airoha Technology Corp., Hsinchu City (TW)

(72) Inventors: Yu-Tsung Lu, Hsinchu County (TW); Hsiang-Chao Huang, Hsinchu (TW); I-Jung Wang, Hsinchu County (TW)

(73) Assignee: Airoha Technology Corp., Hsinchu City (TW)

(21) Appl. No.: 19/008,608

(22) Filed: Jan. 2, 2025

Related U.S. Application Data
(60) Provisional application No. 63/625,220, filed on Jan. 25, 2024.

(51) Int. Cl. H04B 10/50; H01S 5/0683; H04B 10/564

(52) U.S. Cl. CPC H04B 10/504; H01S 5/06832; H04B 10/564

(57) ABSTRACT

An optical modulation amplitude (OMA) controller circuit includes an input port, a processing circuit, and an output port. The input port receives an average output power control setting that is used for controlling an average output power of a laser diode. The processing circuit controls an OMA signal according to at least the average output power control setting. The output port outputs the OMA signal for controlling an OMA of the laser diode.

### CROSS REFERENCE TO RELATED APPLICATIONS

This application claims the benefit of U.S. Provisional Application No. 63/625,220, filed on Jan. 25, 2024. The content of the application is incorporated herein by reference.

### BACKGROUND OF THE INVENTION

### 1. Field of the Invention

The present invention relates to a laser diode control scheme, and more particularly, to a method and apparatus for generating an optical modulation amplitude (OMA) signal according to an average output power control setting of a laser diode.

### 2. Description of the Prior Art

A distributed feedback (DFB) laser diode in a bi-directional optical sub-assembly (BOSA) is a type of semiconductor laser that offers high stability and good modulation characteristics. The characteristics of the DFB laser diode may vary when the temperature changes. There is a need to stabilize P_{AV} (average output power) and ER (extinction ratio) of the DFB laser diode. One conventional approach is to use a lookup table (LUT) for controlling the DFB laser diode in an open-loop manner. However, in most cases, the LUT-based open-loop control may not be practical due to its low accuracy. Thus, there is a need for an innovative laser diode control design capable of maintaining an extinction ratio of a laser diode (e.g., a DFB laser diode in a BOSA).

### SUMMARY OF THE INVENTION

One of the objectives of the claimed invention is to provide a method and apparatus for generating an OMA signal according to an average output power control setting of a laser diode and an associated method.

According to a first aspect of the present invention, an exemplary OMA controller circuit is disclosed. The exemplary OMA controller circuit includes an input port, a processing circuit, and an output port. The input port is arranged to receive an average output power control setting, wherein the average output power control setting is used for controlling an average output power of a laser diode. The processing circuit is arranged to control an OMA signal according to at least the average output power control setting. The output port is arranged to output the OMA signal for controlling an OMA of the laser diode.

According to a second aspect of the present invention, an exemplary OMA control method is disclosed. The exemplary OMA control method includes: receiving an average output power control setting, wherein the average output power control setting is used for controlling an average output power of a laser diode; controlling an OMA signal according to at least the average output power control setting; and outputting the OMA signal for controlling an OMA of the laser diode.

According to a third aspect of the present invention, an exemplary optical system is disclosed. The exemplary optical system includes a laser diode, a monitor photodiode, an average output power controller circuit, an OMA controller circuit, a first comparator circuit, a second comparator circuit, and a laser diode driver circuit. The monitor photodiode is arranged to monitor an output of the laser diode to generate a feedback output. The average output power controller circuit is arranged to receive an average output power control setting, and generate an average output power signal according to the average output power control setting. The OMA controller circuit is arranged to receive the average output power control setting, and generate an OMA signal according to at least the average output power control setting. The first comparator circuit is arranged to compare the average output power signal with a first feedback signal derived from the feedback output, and generate a first comparator output. The second comparator circuit is arranged to compare the OMA signal with a second feedback signal derived from the feedback output, and generate a second comparator output. The laser diode driver circuit is arranged to drive the laser diode according to the first comparator output and the second comparator output.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a diagram illustrating an optical modulation amplitude controller circuit according to an embodiment of the present invention.

FIG. 2 is a diagram illustrating an optical system using the proposed optical modulation amplitude controller circuit according to an embodiment of the present invention.

### DETAILED DESCRIPTION

Certain terms are used throughout the following description and claims, which refer to particular components. As one skilled in the art will appreciate, electronic equipment manufacturers may refer to a component by different names. This document does not intend to distinguish between components that differ in name but not in function. In the following description and in the claims, the terms “include” and “comprise” are used in an open-ended fashion, and thus should be interpreted to mean “include, but not limited to . . . ”. Also, the term “couple” is intended to mean either an indirect or direct electrical connection. Accordingly, if one device is coupled to another device, that connection may be through a direct electrical connection, or through an indirect electrical connection via other devices and connections.

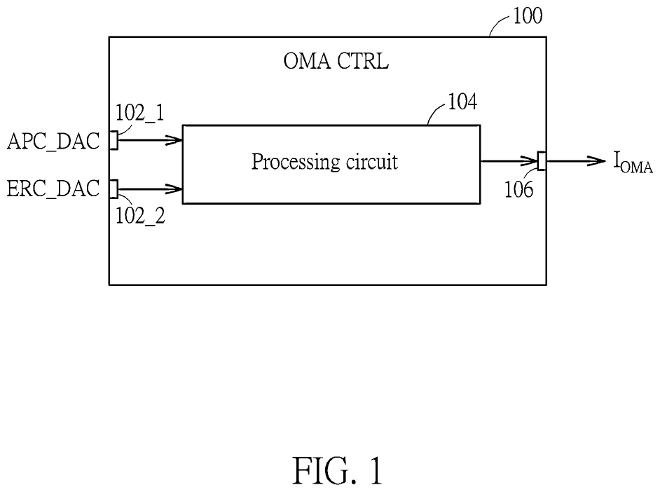

FIG. 1 is a diagram illustrating an optical modulation amplitude (OMA) controller circuit according to an embodiment of the present invention. The OMA controller circuit (labeled by “OMA CTRL”) 100 includes a plurality of input ports 102_1, 102_2, a processing circuit 104, and an output port 106. The input ports 102_1, 102_2 are used to receive control settings of a laser diode. In this embodiment, the input port 102_1 is arranged to receive an average output power control setting APC_DAC, and the input port 102_2 is arranged to receive an extinction ratio control setting ERC_DAC. The average output power control setting APC_DAC is used for controlling an average output power P_{AV} of the laser diode. The extinction ratio control setting ERC_DAC is used for controlling an extinction ratio ER of the laser diode. Both of the average output power control setting APC_DAC and the extinction ratio control setting ERC_DAC may be user-defined settings. The extinction ratio control setting ERC_DAC may be a pre-defined variable set by the user, and may be regarded as a constant after initialization. The average output power control setting APC_DAC may be a variable that can be adjusted by the user anytime. That is, after the average output power control setting APC_DAC is initialized, the user may update the average output power control setting APC_DAC by a different value.

The processing circuit 104 is arranged to control an OMA signal I_{OMA} according to the average output power control setting APC_DAC and the extinction ratio control setting ERC_DAC (which may be a constant after initialization). In some embodiments of the present invention, a ratio of the OMA signal I_{OMA} to an average output power signal I_{AVG} (which is set by the average output power control setting APC_DAC) is maintained at a constant. In some embodiments of the present invention, the OMA signal I_{OMA} generated from the processing circuit 104 may be positively correlated with the average output power control setting APC_DAC. For example, the OMA signal I_{OMA} may be exponentially proportional to the average output power control setting APC_DAC (e.g., I_{OMA}∝2^{APC_DAC}).

The output port 106 is arranged to output the OMA signal I_{OMA} for controlling an OMA of the laser diode. It should be noted that any optical system (particularly, optical transmission system) using the proposed OMA controller circuit 100 falls within the scope of the present invention. For example, the proposed OMA controller circuit 100 may be used by a dual closed-loop block which leverages a photodiode output of a monitor photodiode (MPD) for controlling a laser diode. Specifically, the MPD is used to detect and monitor the output power of the laser diode, and provide feedback information to the dual closed-loop block.

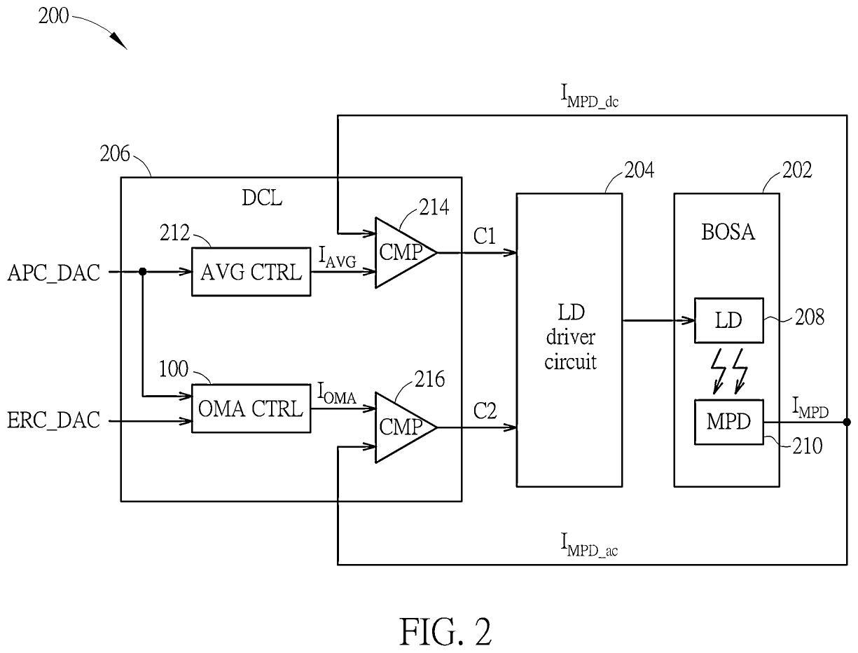

FIG. 2 is a diagram illustrating an optical system (e.g., optical transmission system) using the proposed OMA controller circuit according to an embodiment of the present invention. The optical system 200 includes a BOSA 202, a laser diode (LD) driver circuit 204, and a dual closed-loop block (labeled by “DCL”) 206. The BOSA 202 includes an LD (e.g., DFB laser diode) 208 and an MPD 210. The DCL block 206 supports a dual closed-loop control scheme. In this embodiment, the DCL block 206 includes the proposed OMA controller circuit 100 shown in FIG. 1, and further includes an average output power controller circuit (labeled by “AVG CTRL”) 212 and a plurality of comparator circuits (labeled by “CMP”) 214, 216. The MPD 210 is arranged to monitor an output of the LD 208 to generate a feedback output I_{MPD}. The average output power controller circuit 212 is arranged to receive an average output power control setting APC_DAC, and generate an average output power signal I_{AVG} according to the average output power control setting APC_DAC, where the average output power control setting APC_DAC is used for controlling P_{AV} of the LD 208, and the average output power signal I_{AVG} is indicative of a target P_{AV} value of the LD 208. As mentioned above, the OMA controller circuit 100 is arranged to receive the average output power control setting APC_DAC, and generate the OMA signal I_{OMA} according to at least the average output power control setting APC_DAC, where the OMA signal I_{OMA} is indicative of a target OMA value of the LD 208. Specifically, the OMA signal I_{OMA} may be jointly controlled by the average output power control setting APC_DAC and the extinction ration control setting ERC_DAC.

A direct-current (DC) component of the feedback output I_{MPD} may act as a feedback signal I_{MPD_dc} supplied to the comparator circuit 214. An alternating-current (AC) component of the feedback output I_{MPD} may act as a feedback signal I_{MPD_ac} supplied to the comparator circuit 216. The feedback signal I_{MPD_dc} is indicative of a current P_{AV} value of the LD 208. The feedback signal I_{MPD_ac} is indicative of a current OMA value of the LD 208. The comparator circuit 214 is arranged to compare the average output power signal I_{AVG} with the feedback signal I_{MPD_dc}, and generate a comparator output C1 indicative of an error between the average output power signal I_{AVG} (i.e., target P_{AV} value) and the feedback signal I_{MPD_dc} (i.e., current P_{AV} value). The comparator circuit 216 is arranged to compare the OMA signal I_{OMA} with the feedback signal I_{MPD_ac}, and generate a comparator output C2 indicative of an error between the OMA signal I_{OMA} (i.e., target OMA value) and the feedback signal I_{MPD_ac} (i.e., current OMA value).

The LD driver circuit 204 is arranged to drive the LD 208 according to the comparator outputs C1 and C2. For example, the LD driver circuit 204 may have a P_{AV} control circuit and an OMA control circuit. Due to inherent characteristics of the closed-loop control, the LD driver circuit 204 adjusts driving of the LD 208 to minimize the comparator output C1 (i.e., error between I_{AVG} and I_{MPD_dc}) and the comparator output C2 (i.e., error between I_{OMA} and I_{MPD_ac}). Hence, the P_{AV} of the LD 208 has the target P_{AV} value when I_{MPD_dc}=I_{AVG}, and the OMA of the LD 208 has the target OMA value when I_{MPD_ac}=I_{OMA}.

The OMA, P_{AV}, and ER of the LD 208 may be expressed using the following formulas.

$$OMA = {P}_{1} - {P}_{0} \qquad ( 1 )$$

$${P}_{A V} = \frac{1}{2} ( {P}_{1} + {P}_{0} ) \qquad ( 2 )$$

$$ER = \frac{{P}_{1}}{{p}_{0}} \qquad ( 3 )$$

In above formulas (1), (2), and (3), P₁ represents an optical output power at signal one (i.e., optical transmission power of “1”), and P₀ represents an optical output power at signal zero (i.e., optical transmission power of “0”).

The relationship among OMA, P_{AV}, and ER may be expressed using the following formula.

$$\frac{OMA}{{P}_{A V}} = \frac{2 ( {P}_{1} - {P}_{0} )}{( {P}_{1} + {P}_{0} )} = \frac{2 ( ER - 1 )}{( ER + 1 )} = constant \qquad ( 4 )$$

From the formula (4), the ratio OMA/P_{AV} is a constant if ER is a constant, and vice versa. Thus, to maintain a constant ER, one must maintain a constant ratio OMA/P_{AV}.

Based on above observation, a hardware design of the proposed OMA controller circuit 100 adjusts the OMA in response to variation of P_{AV} set by the user, to maintain the ratio OMA/P_{AV} as a constant. For example, when the user adjusts the average output power control setting APC_DAC for reducing the P_{AV} by 3 dB (i.e., P_{AV} is halved), the proposed OMA controller circuit 100 automatically changes the OMA signal I_{OMA} in response to the average output power control setting APC_DAC, for reducing the OMA by 3 dB (i.e., OMA is halved). The use of the proposed OMA controller circuit 100 enables the user to increase or decrease P_{AV} under a condition that ER remains unchanged.

In this embodiment, the average output power controller circuit 212 adjusts the average output power signal I_{AVG} in response to variation of the average output power control setting APC_DAC, and the OMA controller circuit 100 adjusts the OMA signal I_{OMA} in response to variation of the same average output power control setting APC_DAC. For example, the average output power controller circuit 212 and the OMA controller circuit 100 are designed to have particular behaviors that may be expressed using the following formulas.

$${I}_{A V G} = m \times {2}^{APC \_ DAC} \qquad ( 5 )$$

$${I}_{OMA} = n \times {2}^{APC \_ DAC} \times ERC\_DAC \qquad ( 6 )$$

In above formulas (5) and (6), n and m are coefficients, and ERC_DAC is a pre-determined variable set by the user, and may be regarded as a constant after initialization.

As mentioned above, due to inherent characteristics of the closed-loop control, the LD driver circuit 204 operates to achieve I_{MPD_dc}=I_{AVG} and I_{MPD_ac}=I_{OMA}. Hence, the feedback signals I_{MPD_dc} and I_{MPD_ac} may be expressed using the following formulas.

$${I}_{MPD \_ dc} = m \times {2}^{APC \_ DAC} \qquad ( 7 )$$

$${I}_{MPD \_ ac} = n \times {2}^{APC \_ DAC} \times ERC\_DAC \qquad ( 8 )$$

According to formulas (4), (7), and (8), the relationship among OMA, P_{AV}, and ER may be expressed using the following formula.

$$\frac{OMA}{{P}_{A V}} = \frac{{I}_{MPD \_ ac}}{{I}_{MPD \_ dc}} = \frac{n \times {2}^{APC \_ DAC} \times ERC\_DAC}{m \times {2}^{APC \_ DAC}} = \frac{n \times ERC\_DAC}{m} = constant \qquad ( 9 )$$

In above formula (9), P_{AV} is equivalent to I_{MPD_dc}, and OMA is equivalent to I_{MPD_ac}. When I_{MPD_dc} changes due to adjustment made to the average output power control setting APC_DAC by the user, I_{MPD_ac} must also be adjusted to keep the equality in formula (9) for maintaining a constant ER. This is achieved by the OMA controller circuit 100 designed to generate the OMA signal I_{OMA} that accommodates P_{AV} variation resulting from adjustment of the average output power control setting APC_DAC.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. An optical modulation amplitude (OMA) controller circuit comprising:
an input port, arranged to receive an average output power control setting, wherein the average output power control setting is used for controlling an average output power of a laser diode;
a processing circuit, arranged to control an OMA signal according to at least the average output power control setting; and
an output port, arranged to output the OMA signal for controlling an OMA of the laser diode.

2. The OMA controller circuit of claim 1, wherein a ratio of the OMA signal to an average output power signal set by the average output power control setting is maintained at a constant.

3. The OMA controller circuit of claim 1, wherein the OMA signal is positively correlated with the average output power control setting.

4. The OMA controller circuit of claim 3, wherein the OMA signal is exponentially proportional to the average output power control setting.

5. The OMA controller circuit of claim 1, wherein the OMA controller is arranged to control the OMA of the laser diode included in a bi-directional optical sub-assembly (BOSA).

6. An optical modulation amplitude (OMA) control method comprising:
receiving an average output power control setting, wherein the average output power control setting is used for controlling an average output power of a laser diode;
controlling an OMA signal according to at least the average output power control setting; and
outputting the OMA signal for controlling an OMA of the laser diode.

7. The OMA control method of claim 6, wherein a ratio of the OMA signal to an average output power signal set by the average output power control setting is maintained at a constant.

8. The OMA control method of claim 6, wherein the OMA signal is positively correlated with the average output power control setting.

9. The OMA control method of claim 8, wherein the OMA signal is exponentially proportional to the average output power control setting.

10. The OMA control method of claim 6, wherein the OMA signal is used to control the OMA of the laser diode included in a bi-directional optical sub-assembly (BOSA).

11. An optical system comprising:
a laser diode;
a monitor photodiode, arranged to monitor an output of the laser diode to generate a feedback output;
an average output power controller circuit, arranged to receive an average output power control setting, and generate an average output power signal according to the average output power control setting;
an optical modulation amplitude (OMA) controller circuit, arranged to receive the average output power control setting, and generate an OMA signal according to at least the average output power control setting;
a first comparator circuit, arranged to compare the average output power signal with a first feedback signal derived from the feedback output, and generate a first comparator output;
a second comparator circuit, arranged to compare the OMA signal with a second feedback signal derived from the feedback output, and generate a second comparator output; and
a laser diode driver circuit, arranged to drive the laser diode according to the first comparator output and the second comparator output.

12. The optical system of claim 11, wherein a ratio of the OMA signal to the average output power signal is maintained at a constant.

13. The optical system of claim 11, wherein the OMA signal is positively correlated with the average output power control setting.

14. The optical system of claim 13, wherein the OMA signal is exponentially proportional to the average output power control setting.

15. The optical system of claim 11, wherein the laser diode and the monitor photodiode are included in a bi-directional optical sub-assembly (BOSA).
